(19) United States
(12) Patent Application Publication
(10) Pub. No.: US 2008/0308886 A1
(43) Pub. Date: Dec. 18, 2008

(54) Semiconductor Sensor

(75) Inventors: Udo Ausserlechner, Villach (AT); Siegfried Krainer, Treffen (AT); Helmut Wietschorke, Regensburg (DE)

Correspondence Address: INFINEON TECHNOLOGIES AG;Patent Department, MUC 11.1.507, P.O. Box 221644, Munich, 80506, DE

(73) Assignee: INFINEON TECHNOLOGIES AG, Muenchen (DE)

(21) Appl. No.: 11/763,472

(22) Filed: Jun. 15, 2007

(51) Int. Cl. H01L 29/82; H01L 43/00

(52) U.S. Cl. 257/421; 257/414; 257/E43.003; 257/E29.323

(57) ABSTRACT

This application relates to a semiconductor sensor comprising a carrier that comprises a first surface and a second surface; a sensor chip attached to the first surface; attachment means on the second surface; and mould material applied over the sensor chip and the attachment means.

### FIELD OF THE INVENTION

The present invention relates to semiconductor sensor.

### BACKGROUND

There is an ever increasing demand for smaller, more precise, more intelligent and cheaper sensor devices in science, industry, and consumer markets. In recent years, due to the rapid progress in semiconductor process technology, many of the sensor devices have been transformed to become integrated semiconductor sensors. For these and other reasons, there is a need for the present invention.

### SUMMARY

Accordingly, there is provided a semiconductor sensor comprising a carrier comprising a first surface and a second surface, a sensor chip attached to the first surface, attachment means on the second surface, and mould material applied over the sensor chip and the attachment means.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIGS. 1A and 1B disclose an embodiment of a semiconductor sensor comprising a sensor chip attached to a first surface of a carrier and attachment means on a second surface of the carrier wherein the sensor chip is enclosed in molding material.

FIG. 2 discloses data of lateral mechanical stress on a surface of a sensor chip depending on the degree of delamination of the mould material from the carrier.

FIGS. 3A and 3B disclose a further embodiment of a sensor chip comprising a sensor chip attached to a carrier with attachment means on the second surface, wherein the attachment means are realized by an array of openings imparted into the carrier.

FIGS. 4A and 4B disclose a further embodiment of a sensor chip comprising a sensor chip attached to a carrier with attachment means on the second surface, wherein the attachment means are realized by an array of protrudings on the second surface of the carrier.

FIGS. 5A and 5B disclose a further embodiment of a sensor chip comprising a sensor chip attached to a carrier with attachment means on the second surface, wherein the attachment means are realized by an array of protrudings on the second surface of the carrier and the carrier is the die pad of a Single In-Line Pin (SIP) leadframe.

FIGS. 6A and 6B disclose a further embodiment of a sensor chip like in FIGS. 5A and 5B wherein the attachment means are realized by a single opening in the central region of the second surface of the die pad

FIGS. 7A and 7B disclose a further embodiment of a sensor chip like in FIGS. 6A and 6B wherein the attachment means are realized by a single through-hole through the die pad in the central region of the second surface of the die pad.

FIGS. 8A and 8B disclose a further embodiment of a sensor chip like in FIGS. 6A and 6B wherein the attachment means are realized by a single anchoring recess opening in the central region of the second surface of the die pad.

FIGS. 9A and 9B disclose a further embodiment of a sensor chip like in FIGS. 6A and 6B wherein the attachment means are realized by a single anchoring recess through-hole in the central region of the second surface of the die pad.

FIGS. 10A and 10B disclose a further embodiment of a sensor chip like in FIGS. 6A and 6B wherein the attachment means are realized by a single protruding in the central region of the second surface of the die pad.

FIG. 11 discloses schematically a temperature sensor (Thermistor) integrated into a semiconductor chip.

FIG. 12 discloses schematically a first Hall-sensor integrated into a semiconductor chip.

FIG. 13 discloses schematically a further Hall-sensor integrated into a semiconductor chip.

### DETAILED DESCRIPTION

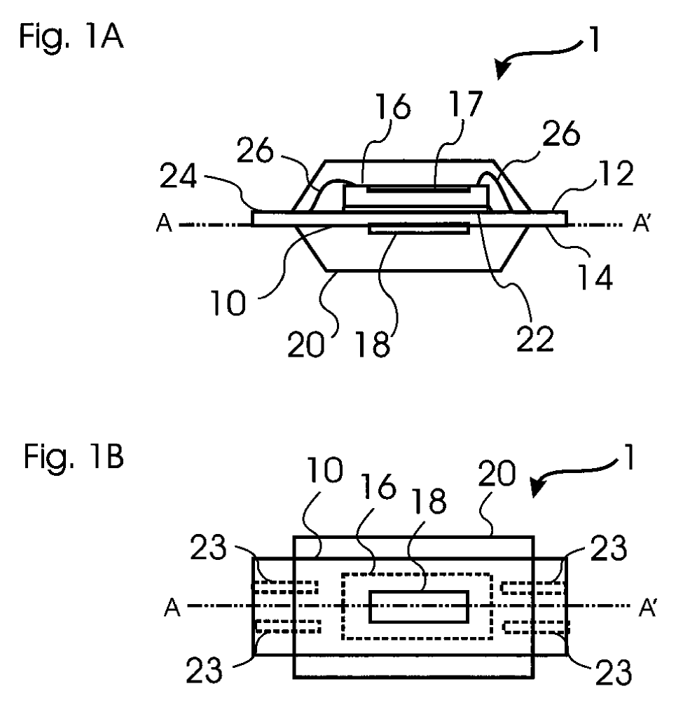

FIGS. 1A and 1B schematically illustrate cross sections of a first embodiment of a semiconductor sensor 1 along two orthogonal planes along axis AA′. Semiconductor sensor 1 comprises a carrier 10 having a first surface 12 (“frontside surface”) and an opposite second surface 14 (“backside surface”). Carrier 10 may be made of metal, of insulating material (e.g. a ceramic or laminate), the die pad of a leadframe having one or several leads 24, or any other structure that can carry a sensor chip. In the present embodiment, carrier 10 is a ceramic substrate having outside connections realized by four conducting lines 23 disposed on the ceramic substrate 10. In FIG. 1B, conducting lines 23 and sensor chip 16 are shown as dashed lines since they lie outside of the cross section plane of FIG. 1B.

FIGS. 1A and 1B further disclose a sensor chip 16 attached to the first surface 12 of ceramic substrate 10 by means of an electrically insulating gluing layer 22. However, depending on the type of carrier, type of sensor chip and application, sensor chip 16 may also be attached by other means, e.g., by a electrically conducting gluing layer, taping, soldering, or by welding. Further, in FIGS. 1A and 1B, sensor chip 16 is electrically connected to the conducting lines 23 by means of bond wires 26. However, the sensor chip may also be electrically connected to the carrier in a flip-chip formation via soldering balls or bumps, or any other appropriate way.

FIGS. 1A and 1B further display attachment means 18 on the second surface 14 of the carrier, and mould material 20 applied to sensor chip 16 and attachment means 18. Generally, the mould material 20 covers the sensor chip 16 hermetically to protect sensor chip 16 from physical or chemical destruction by the outside environment (scratching, humidity, chemical pollution, etc). However, the mould material 20 also may cover sensor chip 16 only partially. For example, for measuring environmental parameters like pressure, electromagnetic radiation, or temperature, the mould material may be structured to provide for a window for exposing the sensitive region of a sensor chip to the outside. Typically, the mould material 20 is molded to some standard shape in order to be transportable and mountable to a PCB by standard assembly equipment. The mould material 18 may be any polymer, or any other plastic material, that can be molded to enclose the sensor chip 16 and the carrier 10.

Attachment means 18 serve to provide for a better attachment of the mould material 20 to the second surface 14 of carrier 10. Attachment means may by any means that provide for an improved attachment of the mould material 20 to the second surface 14, compared to an attachment without the attachment means. For example, attachment means 18 may be realized by imparting a surface structure into the second surface 14 that increases the effective surface area to yield a better adhesion. This can be achieved, e.g., by chemical or mechanical roughening or punching of the second surface 14. Further, attachment structure 18 may be structured in a way that provides mechanical engagement or anchoring of the mold material 20 with the carrier 14. For example, the carrier may have on its second surface 14 hillocks, openings, or through-holes through the carrier, that engage with the mould material 20. Alternatively, or in addition, it may be possible to realize the attachment means 18 by chemical adhesion, e.g. by applying glue, a gluing layer, or tape onto the second surface 14 that improves the adhesion of the mould material 20 to the carrier 10.

As it turns out, the use of attachment means 18 on the second surface 14 of carrier 10 may help decrease sensor performance drifts over time. As found out, a delamination of mould material 20 from the backside surface 14 progressing over time may change the lateral mechanical stress on the active surface of the sensor chip. The lateral mechanical stress on the active region 17 of the sensor chip 16, in turn, changes the operational parameters causing the sensor performance to drift over time. Since progressing delamination cannot be measured or compensated for, the performances drift leads to an overall deterioration of measurement performance.

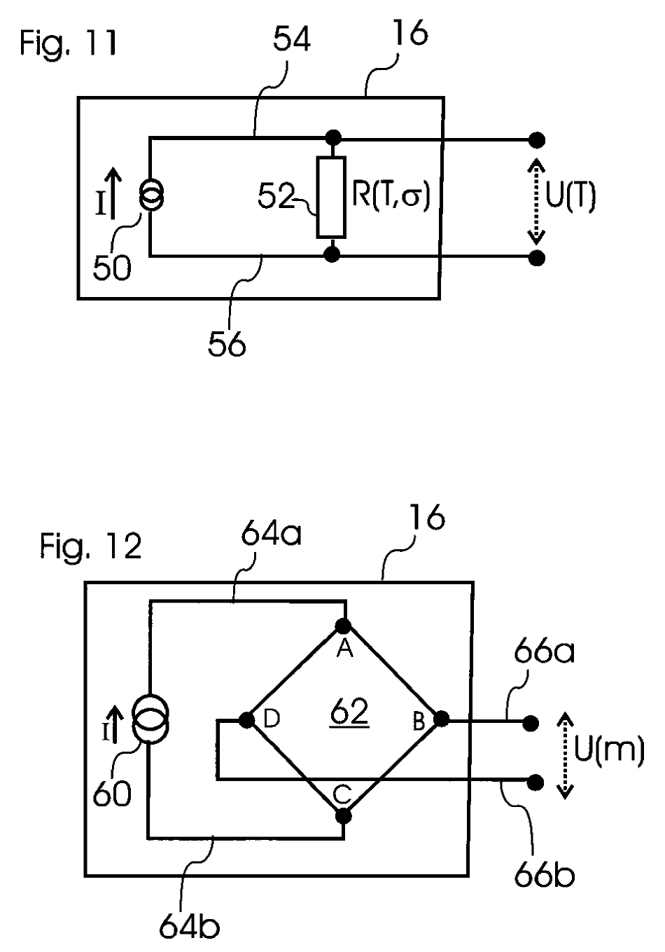

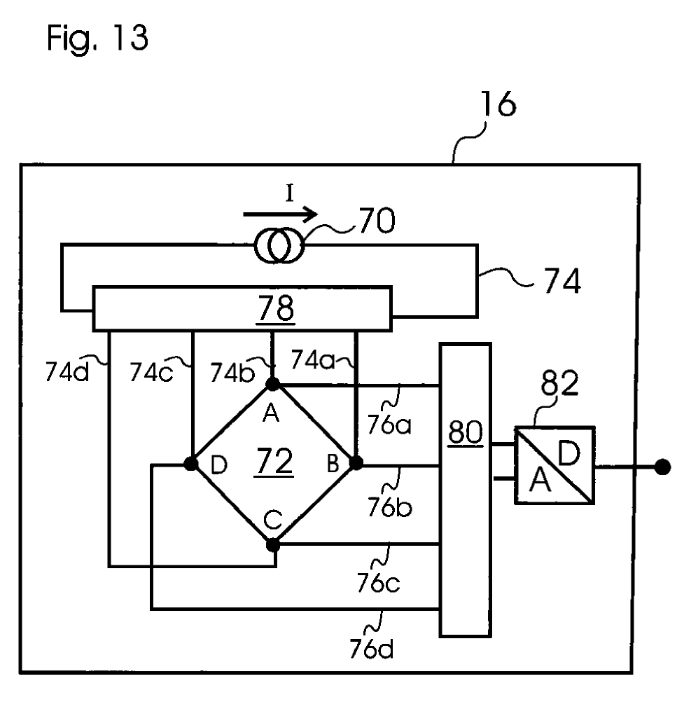

Examples of semiconductor sensors whose performances suffer from drift of the lateral stress drift on the chip surfaces are the temperature sensor shown in FIG. 11, and the Hall sensors shown in FIGS. 12 and 13.

FIG. 11 shows an integrated resistor 52 integrated in a semiconductor chip 16. The semiconductor chip 16 may be made of silicon, germanium, or a compound material, like GaAs or any other III-V semiconductor compound. The integrated resistor 52 may be manufactured according to standard semiconductor manufacturing processes, for example by implantation or by diffusion of p-type or n-type material into the chip or wafer. In the present case, the integrated resistor 52 is manufactured by selectively doping a region of the silicon chip 16 with neutrons that transform some of the silicon atoms into phosphor. Neutron doped silicon is known to provide a resistance R that delivers a highly reproducible temperature dependence.

FIG. 11 further discloses that, after production of the integrated resistor 52, one end of the integrated resistor is connected to a first port of current source 50 via first conducting line 54, and the other end of the integrated resistor is connected via second conducting line 56 to a second port of the current source 50. The current source 50 may be manufactured before, during or after the manufacturing of the integrated resistor 52. Note that the current source 50 may comprise one or several integrated resistors (not shown) that are of the same type as the integrated resistor 52.

The temperature measurement of the temperature sensor of FIG. 11 is based on the effect that the resistances of integrated resistors depend on the temperature. Accordingly, with a constant current I driven by current source 50, an output voltage U is generated across the resistance that reflects the temperature via Ohm's law:

U(T)=R(T)×I.

However, as indicated in FIG. 11, the resistance R(T) of the integrated resistor may also depend on the lateral stress σ on the surface of the resistor, i.e. on the chip surface. For a given temperature T, the dependence of the resistance may be given by:

R(σ)=R0(1+P×σ), wherein:

R0 stands for the resistance without external stress;

P stands for the piezo-resistive coefficient of a given resistor material; and

σstands for the lateral mechanical stress

Accordingly, without control of lateral stress within the integral resistor, temperature measurements with the temperature sensor of FIG. 11 may not be reproducible.

FIG. 12 schematically illustrates a Hall-sensor which is a further semiconductor sensor type whose performance may suffer from drift of lateral stress on the chip surface. In FIG. 12, a Hall-plate 62 is integrated in a mono-crystalline silicon chip 16 within the (100) plane, or (111) plane. Alternatively, the Hall-plate 62 may also be made of GaAs or any other semiconductor material. The production of a Hall-plate can be done in standard methods. In the present case, Hall-plate 62 is formed by implanting n-type material into a square-shaped region on the surface of silicon substrate 16. Further, electrical contacts A, B, C and D are formed on the implantation region to allow for connecting contacts A and C to current source 60 via respective first and second conducting lines 64a, 64b, and for connecting contacts B and D to respective third and fourth conducting lines 66a, 66b. The current source 60 may be of the same type as the one shown in FIG. 11. Current source 60 is to drive a constant current I through Hall-plate 62 from contact A to contact C.

As is well known, Hall-sensors can measure the strength m of a magnetic field vertically passing through the Hall-plate 62 by measuring an output voltage U(m) that reflects the force by which a given current I is “bent” by the magnetic field. Generally, the output voltage U(m) is given by:

U(m)=R_{H}/d×I×m×G, wherein

m is the magnetic strength in a direction vertical to the Hall-plate;

R_{H} is the Hall-constant;

d is the thickness of the Hall-plate;

I is a constant current passing through the Hall-plate; and

G is a geometric factor between 0 and 1 to adjust to an a given geometrical shape of the Hall-plate.

Further, the sensitivity S of a Hall-sensor to a magnetic field is given by:

S(T,σ):=U/(I×m)=S(T,0)(1+P×σ), wherein

S(T,0) is the sensitivity at no lateral stress at a given temperature;

P is the Piezo-Hall coefficient; and

σ is the lateral stress on the surface of the Hall-plate.

Again, the equation above shows that without control of the lateral stress on the Hall-plate, the sensitivity of the Hall-sensor of FIG. 12 may not be reproducible.

It should be noted that the Hall-sensor of FIG. 12 is a set-up that allows for an accuracy of magnetic field measurements of merely a few Milli-Tesla . The limited precision is due to the fact that the magnetic field induced Hall-sensor signal is small compared to an offset voltage overlaying the signal and that is due to crystal defects within the Hall-plate, to temperature change, and to mechanical stress.

In the meantime, several design options to suppress the offset voltage have been developed. One known design option is the so-called “spinning current” Hall-sensor that compensates for the offset voltage by rotating the current I within the Hall-plate. This is shown schematically in FIG. 13 where a first switching unit 78 uses internal switches (not shown in FIG. 13) to periodically connect the electrical contact pairs A and C, B and D, C and A, and D and B of the Hall-plate 72 one after the other to current source 70 via the respective first, second, third and fourth conducting lines 74a, 74b, 74c, 74d. Each switching from one contact pair to next contact pair represents a clockwise change of the current direction by 90 degrees. At the same time, second switching unit 80 adjusts its switches (not shown in FIG. 13) to connect for each contact pair connected to the current source 70 the respective remaining other contact pairs to analogue-to-digital converter 82 (ADC). By taking magnetic measurements for each current direction and taking the average, the offset voltage can be canceled to a such high degree that the remaining magnetic signal can be measured to a precision of less than 2% over a temperature range between −50 to 150 degree Celsius. The residual error of the measurement of magnetic field is mainly due to the piezo-Hall effect as explained above.

Note that the system of FIG. 13 can be fully integrated on one chip. For example, with the Hall-sensor integrated on a silicon chip, switching units 78, 80 and ADC 82 can be manufactured with standard CMOS technology.

It should be mentioned that the piezo-resistive effect also affects the performance of other types of sensors. For example, the piezo-resistive effect may affect the performance of pressure sensors, acceleration sensors or semiconductor microphones where the membrane or cantilever oscillation is determined by a measurement of the resistance that depends on the membrane or cantilever oscillation amplitude.

Further, a changing lateral stress also affects sensor chip performance in ways other than the piezo-resistive effect. For example, changes of stress in integrated photodiodes, or integrated photodiode arrays, CCDs etc., may influence the sensitivity for light detection due to changes of the leakage currents in the photodiode region that overly the signal due to incoming light.

FIGS. 1A and 1B further disclose that the attachment means 18 are not distributed evenly over the full backside surface 14 but only in a selected region. While it may in many cases be sufficient to have the attachment means evenly 18 distributed over the complete backside surface 14, it was found out that in other cases it is advantageous to locate the attachment means 18 selectively on the backside surface. In particular, it was found out that it is advantageous to locate the attachment means 18 in a region of the backside surface 14 of carrier 10 that is within the lateral range of the carrier 10 and the sensor chip 16, as shown in FIG. 1B. As it turns out locating the attachment means 18 in the central region of the backside region 14 makes sure that, if any delamination at the backside surface 14 should occur over the life time of the device, it occurs first in the outer region of the interface between mould material 20 and carrier 10. As found out, having delamination start at the outer region causes the mechanical lateral stress on the sensor chip 16 to change at a slower rate than delamination starting out from the central region of the backside surface 14.

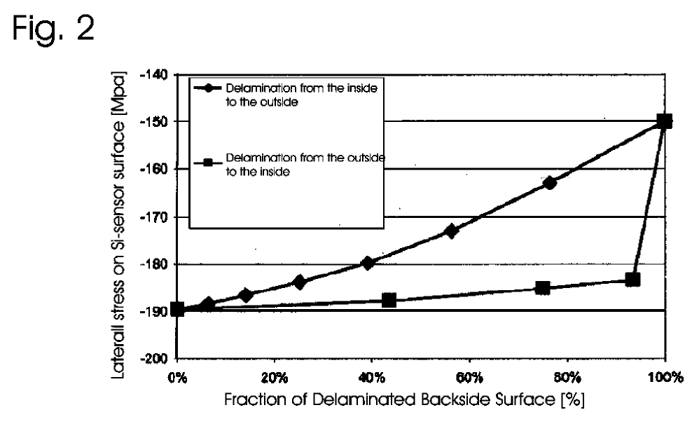

The improvement through a selective application of attachment means 18 to the backside surface 14 of a carrier could be verified in a simulation whose results are summarized in FIG. 2. FIG. 2 shows a diagram where the horizontal axis indicates the fraction of the backside surface region of a copper carrier that is delaminated from the mould material (given in percentage), and the vertical axis indicates the respective lateral stress close to the active surface 17 of the silicon sensor 16 (given in MPa). The diagram further shows two different curves. Curve 1 (indicated by diamonds) corresponds to a simulation where delamination progresses from the center of the backside surface to the outside, while curve 2 (indicated by squares) corresponds to a simulation where the delamination progresses from the outside to the center of the backside surface of the carrier. The results indicate that for a delamination fraction smaller than 90%, the lateral stress on the silicon sensor surface increases less rapidly when delamination on the backside surface progresses from the outside to the inside than delamination from the inside to the outside. Of course, as shown in FIG. 2, once the delamination is 100%, the lateral stress is the same for both curves since it doesn't matter whether the 100% delamination was obtained by delamination from the inside to the outside or from the outside to the inside.

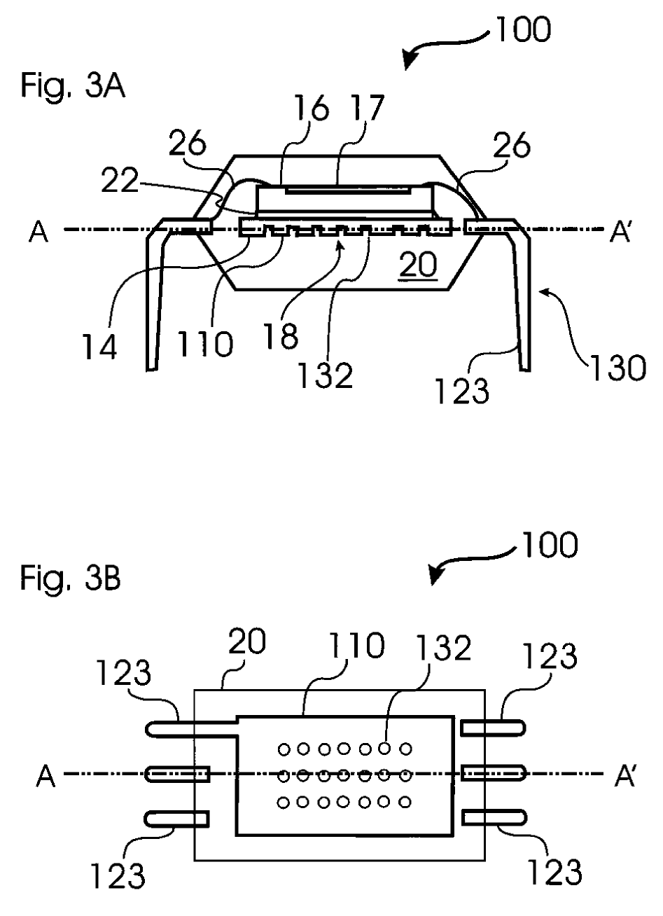

FIGS. 3A and 3B disclose cross sections of a further embodiment of a molded semiconductor sensor 100 comprising a sensor chip 16 with an active region 17, and a conventional leadframe 130 made of a metal, e.g. copper, to which the sensor chip 16 is attached by an insulated gluing layer 22. The leadframe consists of a die pad 110 (“carrier”) that carries the sensor chip 16 and outside connections realized by six leads 123, which may be integrally connected with the die pad 110 or not. In this and the following leadframe embodiments, it is the die pad of the leadframe that is considered the carrier 110 of the sensor chip. In the present case, only one out of the six leads 123 is integrally connected to the die pad 110 while the others are separate. FIGS. 3A and 3B also show two of the bond wires 26 that establish electric connections between the leads 24 and the active region 17 of sensor chip 16.

FIGS. 3A and 3B also disclose mould material 20 that hermetically encloses the sensor chip 16 and partially the leadframe 130. It is only the six leads 123 that extend through the mould material 20. The mould material 20 is usually applied in a transfer molding process in which the leadframe 130 with the sensor chip 16 and the bond wires 26 is inserted into a mould and, after closing the mould, covered with hot fluid mould material pumped into the mould until the inner volume of the mould volume is fully filled. Then, during cool down, the mould material solidifies at some temperature that depends on the type of mould material. Typically, mould material consists of an epoxy, or an epoxy resin, having a filler content, e.g. silicon oxide particles, that is introduced to reduce the coefficient of thermal expansion (CTE) of the epoxy. For such a mould material, solidification takes place at around 170° C. to 200° C. After cooling the mould material down to room temperature, the semiconductor sensor is taken out of the mould. Afterwards, the leads are bent in predetermined ways to comply with some geometry standards used for the through-hole soldering process.

Note that in FIGS. 3A and 3B, the attachment means 18 on the backside surface 14 of die pad 110 are realized by an array of openings 132. Due to the molding process, the openings 132 are covered and filled with the mould material 20. This way, due to the increased effective surface and due to an engagement of the mould material within the openings, the mould material 20 is better attached to the carrier in the region where the array of openings 132 is than in a region without the openings.

Further, it should be noted that the package of the semiconductor sensor 100 complies with the standard of a Through-Hole Device (THD). THDs are mounted to a PCB by feeding the leads of the device through PCB-holes from one side of the PCB to the other and applying some solder to the leads on the other side. An advantage of THDs over Surface-Mounted Devices (SMD) is that the leads are comparably long, e.g. longer than 10 mm, and that during assembly of the device onto a PCB, the device is heated only locally at the distal end of the leads 123 on the opposite side of the PCB. This minimizes the heat transfer to the die pad 110 and the mould material 20 and, accordingly, reduces the threat of delamination of the mould material 20 from the die pad 110 during the soldering process. Therefore, a sensor chip attached to a carrier with attachment means on its backside and connected to through-hole leads is particularly resistant to delamination and any performance drift caused by delamination.

It should also be noted that semiconductor sensor 100 also complies with the standard of a Dual In-Line Pin (DIP) package having the six leads 24 arranged in two parallel lines. Typically, the distance between adjacent leads is 2.54 mm. Such a package is used for small semiconductor chips with only a few input/output pins. For example, the sensor chip 16 of sensor chip 16 may have a chip area of only 20 mm², 10 mm² or less. Packages with such small chip size usually suffer less from delamination than semiconductor sensors that have a large chip size and that require a large array of input/output pins, e.g. a ball grid array. Still, it should be noted that while the number of input/output pins of a ball grid array is usually significantly larger than the number of leads of a DIP, the number of leads of a DIP may well vary from 4 to 32 and more.

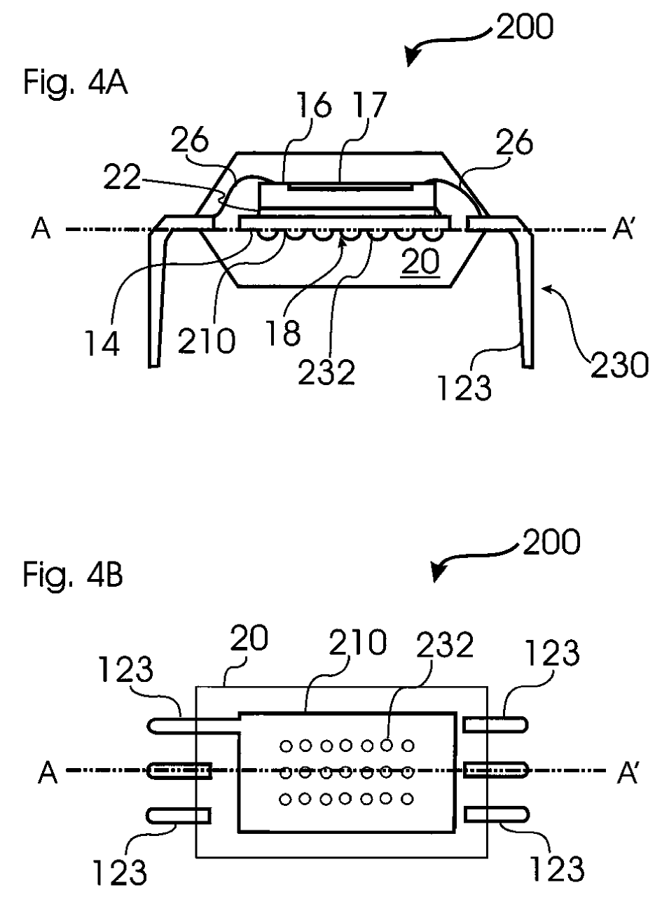

FIGS. 4A and 4B disclose cross sections of a further embodiment of a molded semiconductor sensor 200 along two orthogonal planes extending along axis AA′. The embodiment of semiconductor sensor 200 is essentially the same as of FIGS. 3A and 3B. However, different from FIGS. 3A and 3B, the attachment means 18 in FIGS. 4A and 4B are realized by an array of protrusions 232 that engage with the mould material 20. The protrusions 232 may be of any shape, e.g., they may be cylinder-shaped, spherically shaped, rotationally symmetric, oval, triangular, squared or rectangular shaped, etc. The shape of the protrusions may depend on the way in which they are manufactured. For example, if the protrusions 232 are formed by an etching process selective to a mask, the protrusions may have the same height and a structure that is defined by the structure of the mask. If, however, for example, the protrusions are formed by disposing multiple soldering material lumps on the backside surface 14 that later are heated to reflow, the shape of the protrusions will be solder bump like.

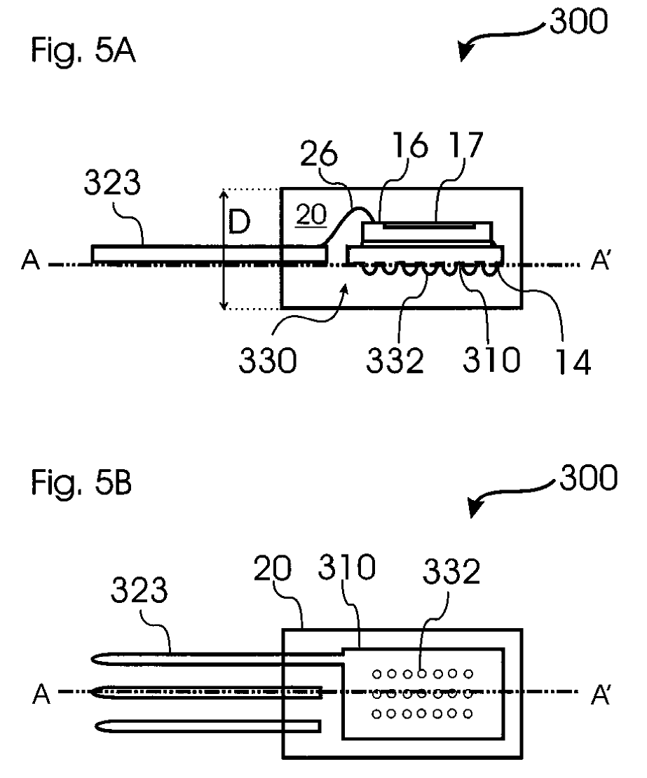

FIGS. 5A and 5B disclose cross sections of a further embodiment of a molded semiconductor sensor 300 that is essentially the same as the one of FIGS. 4A and 4B. However, different from FIGS. 4A and 4B, the leadframe 330 complies with the standard of a Single In-line Pin (SIP) package with the through-hole leads 323 aligned within one line. This package is also known as PSSO (plastic single small outline. In the present embodiment, the package has three leads. However, the standard allows for more than three leads as well. Further, one of the leads 323 is integrally connected with the die pad 310 while the other leads are connected with the sensor chip 16 via bond wires 26. Many magnetic sensors, e.g. Hall sensors, are packaged this way. One lead may be assigned to ground potential, the second lead may be assigned to supply voltage, and the third lead may be assigned to the output signal. The chip size of such sensors may be smaller than the chips in FIGS. 4A and 4B. For example, the chip size may be smaller than 10 mm². At the same time, the thickness D of the mould material package in a direction orthogonal to the backside surface 14 may be reduced to a size smaller than 2 mm. This way, the sensors can be fit in smaller air gaps between magnet poles to be exposable to a stronger magnetic field.

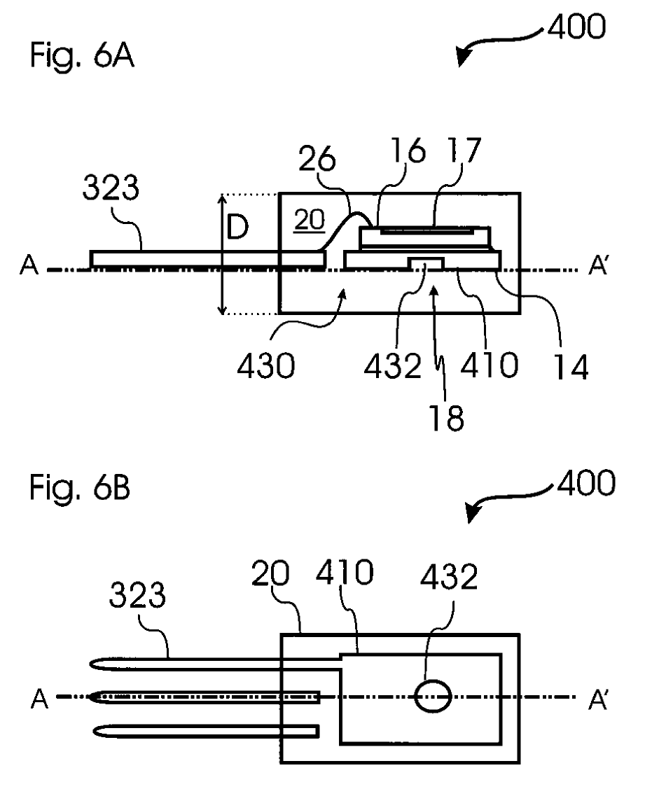

FIGS. 6A and 6B disclose cross sections of a further embodiment of a molded semiconductor sensor 400 that are essentially the same as the ones of FIGS. 5A and 5B. However, different from FIGS. 5A and 5B, the attachment means 18, i.e. the one opening 432 on the backside surface 14 of die pad 410 of leadframe 430, are located only at the center of the die pad 410 and of the sensor chip 16, while leaving a significant area at the outer region of the backside surface 14 without any attachment means. In the present embodiment, the area of the backside surface area that is without attachment means is more than four times larger than the area covered by attachment means 18, i.e. the one opening 432.

The one opening 432 may be formed by a selective etch half way through the die pad 410 (“half-etch”), or by punching, drilling or any other appropriate method. It doesn't need mentioning that, of course, the opening 432 does not have to be circular but can also be rectangular, squared oval or be of any other arbitrary shape.

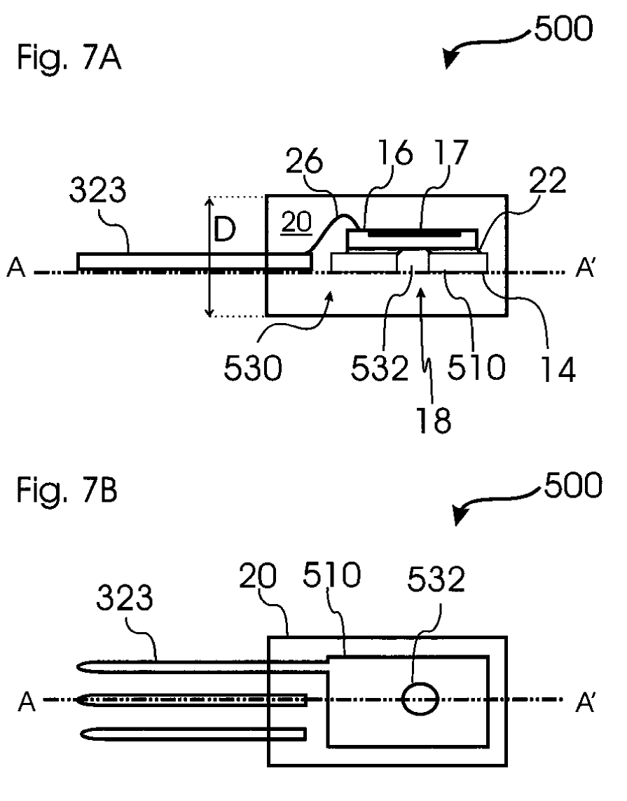

FIGS. 7A and 7B disclose cross sections of a further embodiment of a molded semiconductor sensor 500 that are essentially the same as the ones of FIGS. 6A and 6B. However, different from FIGS. 6A and 6B, the opening 532 in die pad 510 of leadframe 530 is a through-hole through the die pad. This has several advantages since (a) the through-hole can be etched, punched or structured in one step with the leads 524 and the die pad 510; and (b) the through-hole 532 provides a better engagement of the mould material 20 with the die pad 510 due to the larger depth of the through-hole.

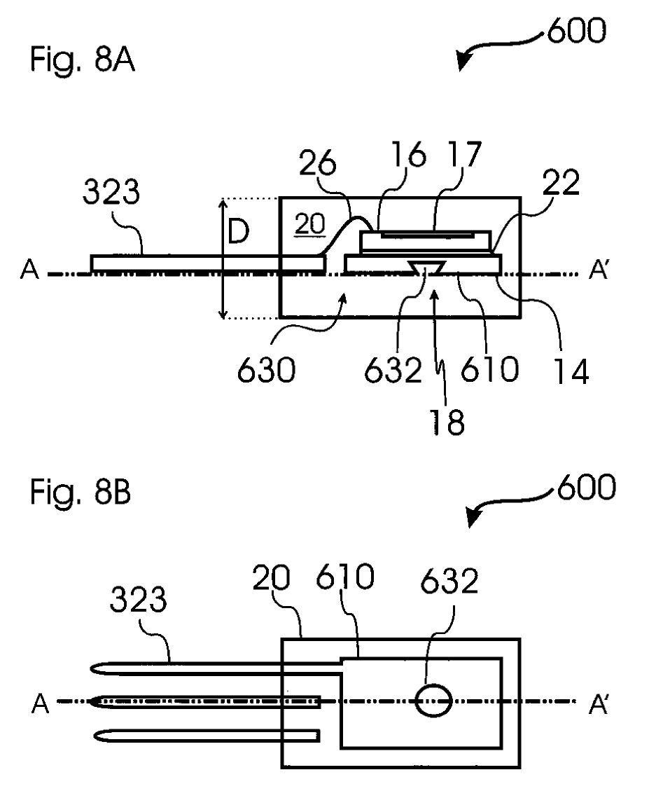

FIGS. 8A and 8B disclose cross sections of a further embodiment of a molded semiconductor sensor 600 that are essentially the same as the ones of FIGS. 7A and 7B. However, different from FIGS. 7A and 7B, the opening 632 in die pad 610 of leadframe 630 has an anchoring recess structure that prevents that mould material 20 within the opening 632 can be removed without breaking the mould material package. The anchoring recess structure of the opening 632 provides a tight attachment of the mould material 20 to the backside surface 14 in the central region of the die pad. Accordingly, delamination on the backside surface 14 in the central region of the die pad is highly suppressed. Again, there are many ways of producing anchoring recess structures in a die pad. One approach is to punch the edges of an opening with a punch such that the edges of the opening are bent inside such that the mouth of the opening is compressed.

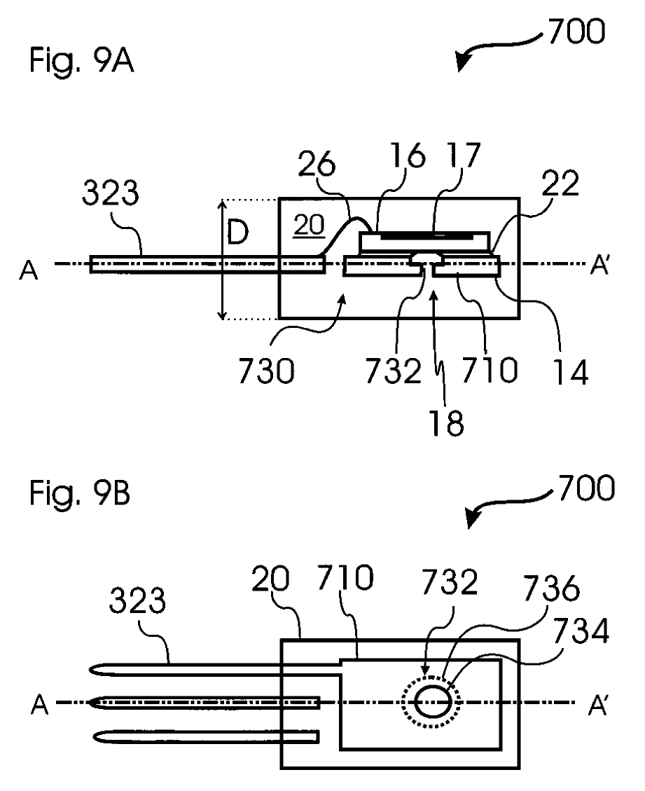

A further method for producing an opening with an anchoring recess structure is disclosed in the sensor chip device 700 of FIGS. 9A and 9B. Sensor chip device 700 is essentially the same as the one shown in FIGS. 8A and 8B. However, different from the sensor chip device in FIGS. 8A and 8B, the opening 732 with the anchoring recess structure in die pad 710 of leadframe 730 has been obtained by a first etch opening the backside surface 14 with a small first cross section 734 and a second etch to open the opposite first surface 12 with a larger second cross section 736 until a through-hole has been obtained. After mounting the sensor chip 16 onto the first surface 12, an anchoring recess opening 732 has been obtained that can be filled with the mould material to keep the mould material 20 attached to the backside surface 14 even when high deformation forces are exerted on the package.

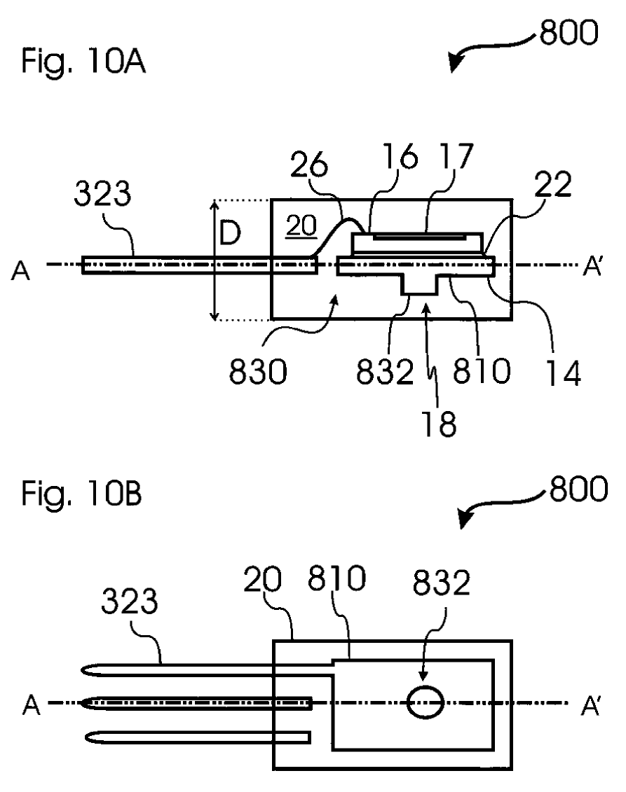

FIGS. 10A and 10B disclose cross sections of a further embodiment of a molded semiconductor sensor 800 that are essentially the same as the ones of FIGS. 6A and 6B to FIGS. 9A and 9B. However, instead of having an opening as attachment means, the attachment means 18 of the semiconductor sensor 800 are realized as a single protrusion 832 integral with and protruding from the backside surface 14 of die pad 810 of leadframe 810. In FIGS. 10A and 10B, the protrusion is cylinder-shaped and positioned in the center region of the backside surface 14. Protrusion 832 in the center region serves (a) to engage the mould material 20 with the backside surface 14 of the die pad 810 for a better attachment, and (b) to stiffen the die pad 810 in the central region of the sensor chip 16 in order to prevent lateral mechanical stress on the sensor chip 16 due to the bending of the chip caused by forces exerted by the mould material 20. Of course, again, it is obvious that the cylinder-shape of protrusion 832 is only one option of many for forming the protrusion. The shape may as well be a block, a cuboid, round, spherical or of a segmented structure, depending on the manufacturing method and application. Typically, the protrusion protrudes by a distance that corresponds to one or two times the thickness of the die pad. Further, the lateral extension of protrusion 832 may be chosen to match the most sensitive region of the sensor chip 16 to help minimizing the bending stress in this region.

Although specific embodiments have been illustrated and described herein, it will be appreciated by those of ordinary skill in the art that a variety of alternate and/or equivalent implementations may be substituted for the specific embodiments shown and described without departing from the scope of the present invention. For example, while the embodiments show attachment means that show a large array of openings or protrusion for engagement, it is well within this focus of the invention that the number or sizes of the holes or protrusions is larger or smaller than the numbers and sizes shown. Further, it is well within the focus of the present invention to combine the various ways by which the attachment means are realized. Further, it is well within the focus of the present invention that the attachment means are applied to carriers other than a die pad, like a ceramic substrate, plastic, glass or the like. Generally, this application is intended to cover any adaptations or variations of the specific embodiments discussed herein. Therefore, it is intended that this invention be limited only by the claims and the equivalents thereof.

What is claimed is:

1. A semiconductor sensor comprising:
a carrier comprising a first surface and a second surface; a sensor chip attached to the first surface;
attachment means on the second surface; and
mould material applied over the sensor chip and the attachment means.

2. The semiconductor sensor according to claim 1 wherein the attachment means are generated on the second surface in a selected region of the second surface.

3. The semiconductor sensor according to claim 2 wherein the ratio of the areas of the selected region to the second surface is smaller than one half.

4. The semiconductor sensor according to claim 2 wherein the ratio of the areas of the selected region to the second surface is smaller than one tenth.

5. The semiconductor sensor according to claim 1 wherein the attachment means comprises an attachment structure integrated into the second surface.

6. The semiconductor sensor according to claim 5 wherein the attachment structure comprises at least one of one or multiple protruding elements, one or multiple openings, and one or multiple anchoring elements.

7. The semiconductor sensor according to claim 1 wherein the attachment means comprises a gluing layer or glue.

8. The semiconductor sensor according to claim 1 wherein the carrier is made of metal.

9. The semiconductor sensor according to claim 1 having a maximum thickness of less than 2 millimeter in a direction orthogonal to first surface.

10. The semiconductor sensor according to claim 1 wherein the area of the sensor chip is smaller than 10 square millimeter.

11. The semiconductor sensor according to claim 1 further comprising a plurality leads extending through the mould material.

12. The semiconductor sensor according to claim 1 being a through-hole device (THD).

13. The semiconductor sensor according to claim 1 being single in-line pin (SIP) device or a dual in-line pin (DIP) device.

14. The semiconductor sensor according to claim 1 wherein the sensor chip comprises at least one of a magnetic sensor, a pressure sensor, an acceleration sensor, a microphone, a micro-electric-mechanical system, a Hall-sensor, a GMR-sensor, a temperature sensor, piezo-resistive sensor element, a piezo-junction sensor element, and a movable element.

15. The semiconductor sensor according to claim 1 wherein the sensor chip comprises at least one of a current source, a p-type diffusion resistor and an n-type diffusion resistor.

16. A semiconductor sensor comprising:
a leadframe comprising a die pad having a first surface and a second surface, wherein the second surface comprises attachment means;
a magnetic sensor attached to the first surface; and
mould material applied over the sensor chip and the second surface.

17. The semiconductor sensor according to claim 16 wherein the attachment means are generated in the center region of the second surface.

18. A semiconductor sensor comprising:
a leadframe comprising a die pad having a first surface and a second surface, wherein the second surface comprises attachment means;
a semiconductor sensor chip comprising an integrated resistor, the semiconductor sensor chip being attached to the first surface; and
mould material applied over the semiconductor sensor chip and the second surface.

19. The semiconductor sensor according to claim 18 wherein the integrated resistor is a mono-crystalline resistor.

20. The semiconductor sensor according to claim 18 wherein the integrated resistor is a poly-crystalline resistor.

21. The semiconductor sensor according to claim 18 wherein the integrated resistor is a resistor implanted into the semiconductor sensor chip.

22. The semiconductor sensor according to claim 18 wherein the integrated resistor is a resistor diffused into the semiconductor sensor chip.
